(19) United States
(12) Patent Application Publication
(10) Pub. No.: US 2004/0146807 A1
(43) Pub. Date: Jul. 29, 2004

(54) Method of fabricating microlens array

(75) Inventors: Myung-Bok Lee, Suwon-City (KR); Jin-Seung Sohn, Seocho-gu (KR); Eun-Hyoung Cho, Gwangju-gun (KR); Young-Pil Park, Seocho-gu (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Suwon-City (KR)

(21) Appl. No.: 10/445,209

(22) Filed: May 27, 2003

(30) Foreign Application Priority Data
Jan. 27, 2003 (KR) 2003-5197

(51) Int. Cl. G03F 7/40

(52) U.S. Cl. 430/311; 430/322; 430/330; 430/313

(57) ABSTRACT

Provided is a method of fabricating a microlens array. The method includes forming a cylindrical photoresist mask on one side of a substrate using a photolithographic process, forming the photoresist mask as a profile corresponding to a microlens by melting the photoresist mask using a reflow process, forming the microlens on the substrate by transferring the profile of the photoresist mask to the substrate using plasma etching, forming a photoresist having a surface profile for refining a curved surface of the microlens on the surface of the microlens, and transferring the curved profile of the photoresist to the surface of the microlens by etching the photoresist using plasma etching. By this method, a high-performance microlens having a precise curved surface, a high numerical aperture (NA), and low aberration can be fabricated.

This application claims the priority of Korean Patent Application No. 2003-5197, filed on Jan. 27, 2003, in the Korean Intellectual Property Office, the disclosure of which is incorporated herein in its entirety by reference.

### BACKGROUND OF THE INVENTION

1. Field of the Invention

The present invention relates to a method of fabricating microlenses, and more particularly, to a method of fabricating a microlens array by transferring the profile of a photoresist mask.

2. Description of the Related Art

Microlenses are used in various places such as displays, imaging devices, and optical communication systems for beam focusing and collimation purposes. Also, a microlens may be applied as an objective lens or a collimator lens of an optical pickup used for recording or reading data in optical disc drives (ODDs) such as CD and DVD. A microlens array may be used as an objective lens array of a parallel optical head, which enables simultaneous writing or reading of data on a plurality of tracks by a plurality of pickups.

FIGS. 1A through 1D are cross-sectional views illustrating a method of fabricating a conventional microlens.

As shown in FIG. 1A, a photoresist 2 is coated on a substrate 1, which is formed of silicon, glass, fused silica, or quartz.

As shown in FIG. 1B, the photoresist 2 is patterned by a photolithographic process so as to form a low cylindrical photoresist mask 2a. Next, a reflow process, which is a thermal process performed at a glass transition temperature or higher, for example, about 150° C., is performed on the photoresist mask 2a. Thus, the photoresist mask 2a is melted by the reflow process and takes on a dome shape due to surface tension acting thereon. Afterwards, as shown in FIG. 1C, by using a resultant dome-shaped photoresist mask 2b as an etch mask, the substrate 1 is dry etched using plasma etching, such as reactive ion etching, in a vacuum chamber under predetermined conditions. Thus, the dome shape of the photoresist mask 2b is transferred to the substrate 1. As a result, microlenses 1a having spherical surfaces are formed as an array on the substrate 1.

According to the conventional method, the low cylindrical photoresist mask 2a is changed into the dome-shaped photoresist mask 2b by the reflow process. That is, the photoresist mask 2b is not aspherical but spherical. Thus, a spherical lens is obtained only from the photoresist mask 2b since the photoresist mask 2b is spherical and transferred to the substrate 1 by the etching process. However, when light is focused by such a spherical lens, spherical aberration occurs. That is, light rays refracted at respective portions of the lens fail to focus to a precise point. It is difficult to use such spherical lenses in precision optical devices, such as objective lenses in optical pickups, which require prevention of spherical aberration.

U.S. Pat. No. 5,286,338 discloses a method of forming an aspherical lens using plasma etching. In this method, while a dome shape of a mask formed by a reflow process is transferred to a substrate as described above, a ratio of etching rates between a mask material and a substrate material is gradually changed so as to form the aspherical lens. Here, the ratio of etching rates is changed by continuously varying a mixture ratio of etching gases during an etching process. However, a ratio of surface areas of the mask material and the substrate material is continuously changed with the etching depth. Further, since reactants and products of the mask are different from those of the substrate, the chemical reactions are complicated and continuously change over time. Therefore, it is extremely difficult to obtain the aspherical profile as designed while changing the kinds and the mixture ratio of etching gases.

U.S. Pat. No. 6,301,051 suggests a method of forming an aspherical microlens array. In this method, to integrate a microlens array on an IC substrate having an optical electronic circuit, a photoresist is coated on a substrate having a planarized acrylic polymer layer and then is patterned using gray scale photolithography. Afterwards, the profile of the photoresist is transferred to the substrate using dry etching, thus obtaining the microlens array. In this case, however, since the photoresist is formed to a very thin thickness of about 1-3 μm, the height of the resultant microlens is only several μm. This makes it difficult to obtain a microlens having a large diameter or a high numerical aperture (NA). Also, because this method involves an ultraviolet exposure process using a gray scale photo-mask instead of a reflow process, when a microlens is formed to have a larger height, the roughness of the curved surface of the microlens becomes very great. Further, as the precision of the curved surface of the microlens depends exclusively on the precision of the gray scale photo-mask, the resultant precision of the microlens has a limit and a microlens having low aberration cannot be obtained.

### SUMMARY OF THE INVENTION

The present invention provides a method of fabricating an array of high-performance microlenses having precise curved surfaces, high numerical apertures (NAs), and low aberration.

In accordance with a first aspect of the present invention, there is provided a method of fabricating a microlens array, comprising:

forming a cylindrical photoresist mask on one side of a substrate using a photolithographic process;

forming the photoresist mask as a profile corresponding to a microlens by melting the photoresist mask using a reflow process;

forming the microlens on the substrate by transferring the profile of the photoresist mask to the substrate using plasma etching;

forming a photoresist having a surface profile for refining a curved surface of the microlens on a surface of the microlens; and

transferring the curved profile of the photoresist to the surface of the microlens by etching the photoresist using plasma etching.

Preferably, forming the photoresist comprises exposing and patterning the photoresist by a photolithographic process using a gray scale photo-mask or by a direct write method using an electron beam or a laser beam.

In accordance with a second aspect of the present invention, there is provided a method of fabricating a microlens array, comprising:

forming a cylindrical photoresist mask on one side of a substrate using a photolithographic process;

forming the photoresist mask as a profile corresponding to a microlens by melting the photoresist mask using a reflow process;

exposing the photoresist mask to a predetermined pattern so as to refine a curved surface of the photoresist mask and then developing the photoresist mask; and

forming the microlens having the profile corresponding to the photoresist mask by transferring the profile of the photoresist mask, whose curved surface is refined using plasma etching, to the substrate.

Preferably, exposing and developing the photoresist mask comprises exposing and patterning the photoresist mask using a gray scale photo-mask, or by a direct write method using an electron beam or a laser beam.

In accordance with a third aspect of the present invention, there is provided a method of fabricating a microlens array, comprising:

forming a cylindrical photoresist mask on one side of a substrate using a photolithographic process;

forming the photoresist mask as a profile corresponding to a microlens by melting the photoresist mask using a reflow process;

forming the microlens on the substrate by transferring the profile of the photoresist mask to the substrate using plasma etching;

coating a photoresist on the other side of the substrate;

patterning the photoresist so as to have a pattern for refining a curved surface of the microlens; and

transferring the profile of the photoresist to the other side of the substrate using plasma etching.

Preferably, patterning the photoresist comprises exposing and patterning the photoresist by a photolithographic process using one of a gray scale photolithography and a direct write method using an electron beam or a laser beam.

### BRIEF DESCRIPTION OF THE DRAWINGS

The above and other features and advantages of the present invention will become more apparent by describing in detail preferred embodiments thereof with reference to the attached drawings in which:

FIGS. 1A through 1D are cross-sectional views illustrating an example of a conventional method of fabricating a microlens array;

FIGS. 2A through 2G are cross-sectional views illustrating a method of fabricating a microlens array according to a first embodiment of the present invention;

FIGS. 3A through 3F are cross-sectional views illustrating a method of fabricating a microlens array according to a second embodiment of the present invention; and

FIGS. 4A through 4G are cross-sectional views illustrating a method of fabricating a microlens array according to a third embodiment of the present invention.

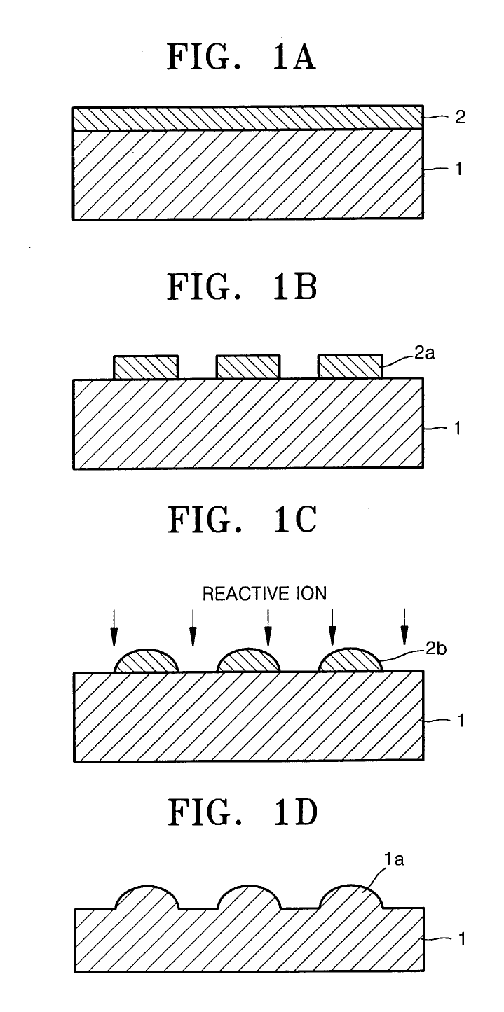

### DETAILED DESCRIPTION OF THE INVENTION

Embodiment 1

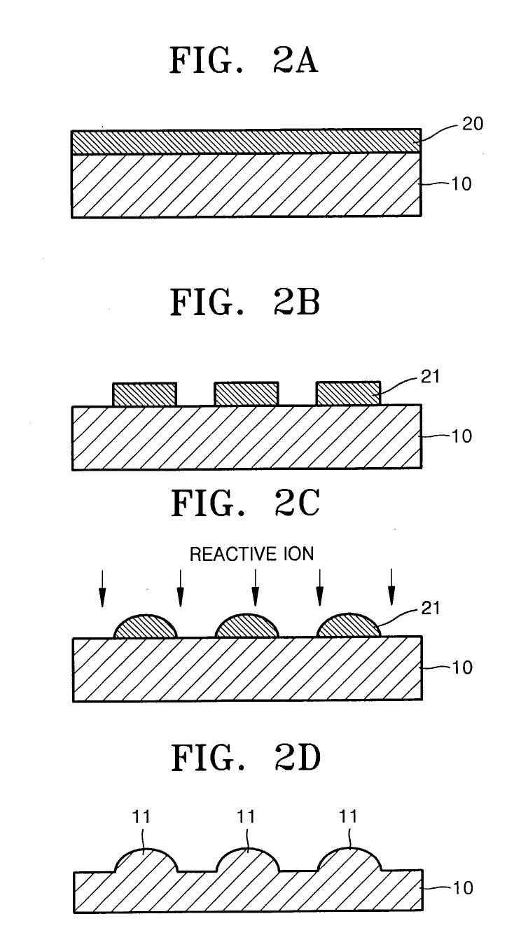

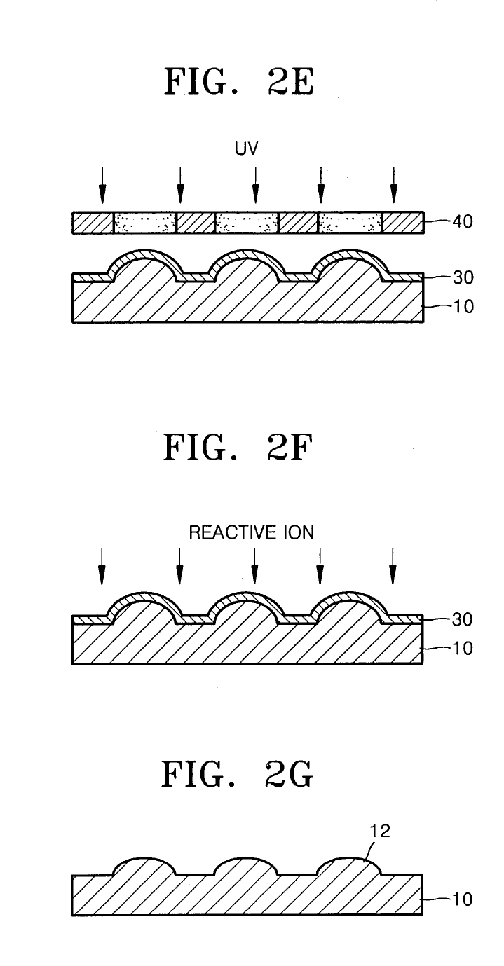

As shown in FIG. 2A, a photoresist 20 is coated on a substrate 10, which is formed of one of silicon, glass, fused silica, and quartz.

As shown in FIG. 2B, the photoresist 20 is patterned using a conventional photolithographic process so as to form a low cylindrical photoresist mask 21. The photoresist mask 21 is reflowed by heating to a glass transition temperature or higher, for example, about 150° C. During the reflow process, surface tension and gravity act on the photoresist mask 21. Thus, as shown in FIG. 2C, the photoresist mask 21 is formed in a dome (or hemispheric) shape. By using the dome-shaped photoresist mask 21 as an etch mask, the substrate 10 is dry etched using plasma etching under predetermined conditions. Thus, the dome shape of the photoresist mask 21 is transferred to the substrate 10 so as to obtain an array of spherical microlenses 11, as shown in FIG. 2D.

As shown in FIG. 2E, a photoresist 30 is coated on the substrate 10 to a predetermined thickness and then is exposed to ultraviolet rays (UV) using a gray scale photo-mask. The gray scale photo-mask is properly designed such that different intensities of the UV rays transmit different portions of the gray scale photo-mask 40 to form the photoresist 30 in an aspherical shape. To produce the gray scale photo-mask 40, a surface profile of a spherical microlens 11 is measured and compared with design specifications. Then, a difference in the etching depth of the photoresist 30 therebetween is represented numerically. Afterwards, to further etch the photoresist 30 according to the numerically represented data, the gray scale photo-mask 40 is manufactured for compensating for the difference in the etching depth. Here, a gray level is set graphically to compensate for the etching depth of the photoresist 30.

As shown in FIG. 2F, the substrate 10 and the photoresist 30 are etched by plasma etching. Thus, the aspherical profile of the photoresist 30 is transferred to the microlenses 11. As a result, as shown in FIG. 2G, a final objective lens array having aspherical microlenses 12 is formed on the substrate 10.

In the present embodiment, the substrate 10 is etched by using the spherical photoresist mask 21 as an etch mask to form the spherical microlenses 11. Next, another photoresist 30 is coated on the substrate 10 and then is exposed to light using a gray scale photo-mask. After this, the substrate 10 and the photoresist 30 are etched such that the spherical microlenses 11 become aspheric.

Embodiment 2

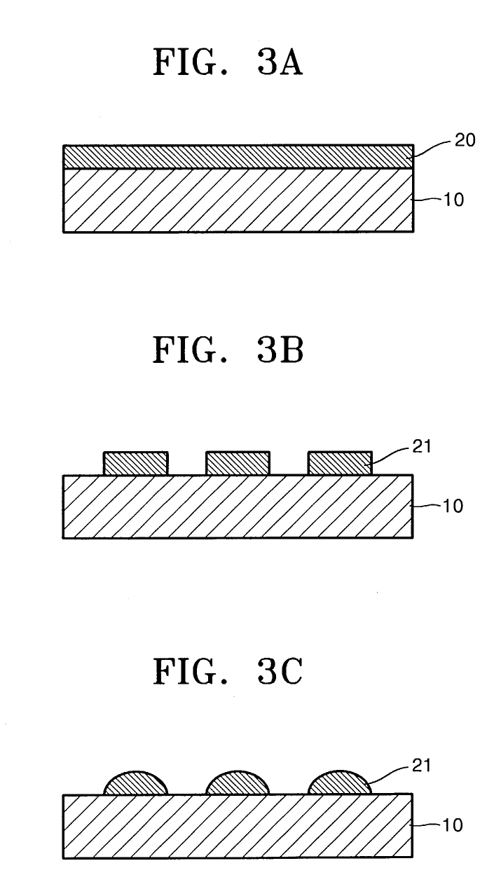

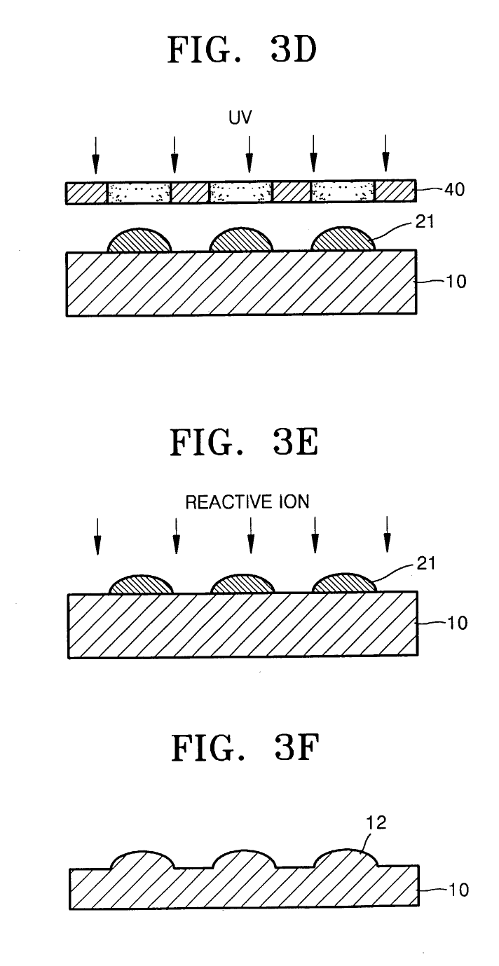

As shown in FIG. 3A, a photoresist 20 is coated on a substrate 10, which is formed of one of silicon, glass, fused silica, and quartz.

As shown in FIG. 3B, the photoresist 20 is patterned using a conventional photolithographic process so as to form a low cylindrical photoresist mask 21. The photoresist mask 21 is heated at a glass transition temperature or higher, for example, about 150° C., using a reflow process. During the reflow process, surface tension and gravity act on the photoresist mask 21. Thus, as shown in FIG. 3C, the photoresist mask 21 is formed in a dome (or hemispheric) shape.

As shown in FIG. 3D, the photoresist mask 21 is exposed to ultraviolet rays (UV) using a gray scale photo-mask 40. To produce the gray scale photo-mask 40, a surface profile of the spherical photoresist mask 21 is measured and then is compared with design specifications. Then, a difference in the etching depth of the photoresist mask 21 therebetween is represented numerically. Afterwards, to further etch the photoresist 30 to make up for the difference in the etching depth, the gray scale photo-mask 40 is manufactured for compensating for the difference in the etching depth. Here, a gray level is set graphically to compensate for the etching depth of the photoresist mask 21.

As shown in FIG. 3D, after being exposed to the UV using the gray scale photo-mask, the photoresist mask 21 is developed to have an aspherical surface.

As shown in FIG. 3E, by using the aspherical photoresist mask 21 as an etch mask, the substrate 10 is dry etched using plasma etching under predetermined conditions. Thus, the aspherical profile of the photoresist mask 21 is transferred to the substrate 10. As a result, as shown in FIG. 3F, an array of microlenses 12 having the aspherical surfaces is formed on the substrate 10.

Embodiment 3

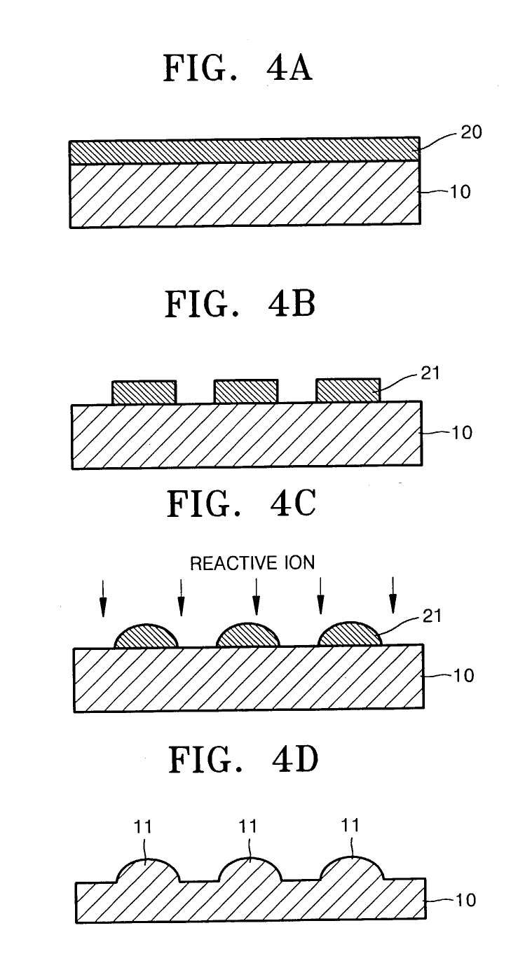

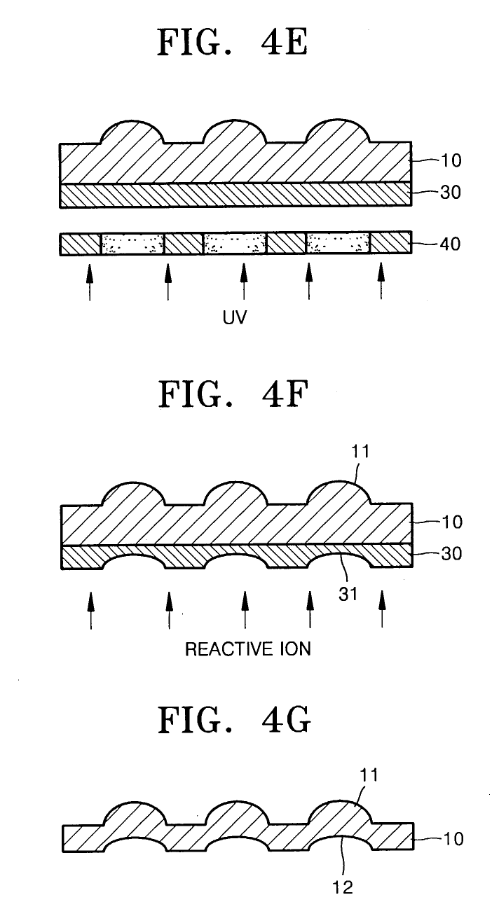

As shown in FIG. 4A, a photoresist 20 is coated on a substrate 10, which is formed of one of silicon, glass, fused silica, and quartz.

As shown in FIG. 4B, the photoresist 20 is patterned using a conventional photolithographic process to form a low cylindrical photoresist mask 21. The photoresist mask 21 is heated at a glass transition temperature or higher, for example, about 150° C., using a reflow process. During the reflow process, surface tension and gravity act on the photoresist mask 21. Thus, as shown in FIG. 4C, the photoresist mask 21 is formed in a dome (or hemispheric) shape. By using the dome-shaped photoresist mask 21 as an etch mask, the substrate 10 is dry etched using plasma etching under predetermined conditions. Thus, the dome shape of the photoresist mask 21 is transferred to the substrate 10 so as to obtain an array of microlenses 11 having spherical surfaces.

As shown in FIG. 4C, the mask 21 and the substrate 10 are etched using plasma etching, such as reactive ion etching, in a vacuum chamber, thereby forming an array of microlenses 11 on the substrate 11, as shown in FIG. 4D.

As shown in FIG. 4E, a photoresist 30 is coated on the backside of the substrate 10 to a predetermined thickness and then is exposed to ultraviolet rays (UV) using a gray scale photo-mask. The gray scale photo-mask 40 is properly designed such that different intensities of the UV rays transmit different portions of the gray scale photo-mask 40 to form the photoresist 30 in an aspherical shape. To produce the gray scale photo-mask 40, a surface profile of the spherical microlens 11 is measured. Then, the gray scale photo-mask 40 is designed such that the photoresist 30 is exposed to form a pattern corresponding to a profile of an aspherical concave lens, which enables compensation of spherical aberration caused by the microlenses 11.

As shown in FIG. 4F, the photoresist 30 positioned below the substrate 10 is etched such that the aspherical concave profile of the photoresist 30 is transferred to a bottom of the substrate 10. As a result, as shown in FIG. 4G, concave compensatory lens units 12 are formed at the bottom of the substrate 10, thereby completing a microlens array.

According to yet another embodiment of the present invention, to correct the profile of the spherical microlens or the spherical photoresist mask, an electron beam or a laser beam may be used in place of the photolithographic process using a gray scale photo-mask. In this case, the intensity of the beam can be varied using a direct write method so as to form a photoresist in a desired shape.

Also, when a gray scale photo-mask is designed, it is possible to partially change a gray level so that a diffraction element, such as a Fresnel lens or a grating, can be simultaneously formed to overlap a curved surface of a lens. This allows an objective lens to compensate not only for spherical aberration but also for the chromatic aberration. Further, even if a direct write method is applied, a pattern corresponding to the diffraction element can be formed on a photoresist.

Also, after performing the second exposure process using a gray scale photo-mask or an electron beam or a laser beam in order to correct error in the surface profile of microlenses, a second reflow process may be performed. That is, the substrate is heated at a glass transition temperature or higher so as to partially melt the photoresist. Thus, the roughness of a surface of the microlens can be improved without a great change in the surface profile affecting optical characteristics.

As explained so far, according to one embodiment of the present invention, a method of fabricating a spherical lens comprises applying a reflow process to a photoresist and then performing plasma etching. A profile of the spherical lens is measured and compared with design specifications. Thus, an error is calculated and then corrected. The error can be corrected by forming a very thin photoresist in the shape of a microlens. In other words, a profile of the microlens is roughly formed by a method of fabricating a spherical lens, and then an aspherical error is finely adjusted. According to the present invention, the precision of a curved surface of the microlens is enhanced compared with the conventional method. The method of fabricating an objective lens according to the present invention has the following merits.

(i) An improved microlens array can be fabricated by adding a few processes to conventional methods of fabricating a microlens array.

(ii) As long as it is possible to precisely form a gray scale photo-mask required for profile correction, or to precisely control the intensity profile of an electronic beam or a laser beam, because other process variables can be fixed, the entire fabricating process is relatively simple.

(iii) A compensatory profile can be applied to all kinds of microlens surfaces, such as a sectional aspherical surface, a double-faced aspherical surface, and a refractive surface where a diffractive pattern is formed.

(iv) As compared to conventional methods of fabricating a spherical lens or an aspherical lens using a gray scale photo-mask, high curved-surface precision and good surface roughness can be obtained. As a result, a microlens having a high NA and low aberration can be fabricated.

(v) The method according to the present invention is suitable for mass production by producing a master mold.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. A method of fabricating a microlens array, comprising:
forming a cylindrical photoresist mask on one side of a substrate using a photolithographic process;
forming the photoresist mask as a profile corresponding to a microlens by melting the photoresist mask using a reflow process;
forming the microlens on the substrate by transferring the profile of the photoresist mask to the substrate using plasma etching;
forming a photoresist having a surface profile for refining a curved surface of the microlens on the surface of the microlens; and
transferring the curved profile of the photoresist to the surface of the microlens by etching the photoresist using plasma etching.

2. The method of claim 1, wherein forming the photoresist comprises forming the photoresist by a photolithographic process using a gray scale photo-mask.

3. The method of claim 1, wherein forming the photoresist comprises exposing and patterning the photoresist by a direct write method using one of an electron beam and a laser beam.

4. A method of fabricating a microlens array, comprising:
forming a cylindrical photoresist mask on one side of a substrate using a photolithographic process;
forming the photoresist mask as a profile corresponding to a microlens by melting the photoresist mask using a reflow process;
exposing the photoresist mask to a predetermined pattern so as to refine a curved surface of the photoresist mask and developing the photoresist mask; and
forming the microlens having the profile corresponding to the photoresist mask by transferring the profile of the photoresist mask, whose curved surface is refined by plasma etching, to a surface of the substrate.

5. The method of claim 4, wherein exposing and developing the photoresist mask comprises exposing and patterning the photoresist mask using a gray scale photo-mask.

6. The method of claim 4, wherein exposing and developing the photoresist mask comprises exposing and patterning the photoresist mask by a direct write method using one of an electron beam and a laser beam.

7. A method of fabricating a microlens array, comprising:
forming a cylindrical photoresist mask on one side of a substrate using a photolithographic process;
forming the photoresist mask as a profile corresponding to a microlens by melting the photoresist mask using a reflow process;
forming the microlens on the substrate by transferring the profile of the photoresist mask to a surface of the substrate using plasma etching;
coating a photoresist on the other side of the substrate;
patterning the photoresist so as to have a pattern for refining a curved surface of the microlens; and
transferring the profile of the photoresist to the other side of the substrate using plasma etching.

8. The method of claim 7, wherein patterning the photoresist comprises forming the photoresist by a photolithographic process using a gray scale photo-mask.

9. The method of claim 7, wherein patterning the photoresist comprises exposing and patterning the photoresist by a direct write method using one of an electronic beam and a laser beam.
